(19) United States
(12) Patent Application Publication
(10) Pub. No.: US 2022/0093581 A1
(43) Pub. Date: Mar. 24, 2022

(54) IC PACKAGE PROVIDING ISOLATED FILTER ON LEAD-FRAME

(71) Applicant: BeRex Inc., Santa Clara, CA (US)

(72) Inventor: Lothar Johannes Maria Musiol, San Clemente, CA (US)

(21) Appl. No.: 17/026,939

(22) Filed: Sep. 21, 2020

(51) Int. Cl. H01L 25/18; H01L 23/00; H01L 23/495

(52) U.S. Cl. CPC H01L 25/18; H01L 24/48; H01L 23/49575; H01L 23/49541; H01L 24/45; H01L 2224/48247; H01L 2224/4801; H01L 2224/45144; H01L 2224/45147; H01L 2224/45169; H01L 2224/48137; H01L 2224/48108

(57) ABSTRACT

A radio frequency transceiver integrated circuit front end chip and package with integrated harmonic filter is designed to present a 50 Ohm impedance to the integrated circuit. The harmonic filter is connected to the antenna with a bond wire inside the package. The device provides reduced size and cost associated with transceiver circuits that are fabricated in CMOS technology and applied as standalone devices.

### BACKGROUND OF THE INVENTION

### Field of the Invention

This invention relates generally to radio frequency (RF) transceiver circuitry, and more particularly to integrated circuit (IC) front end (FE) chips which may include Power Amplifier (PA) circuits and Integrated Passive Devices (IPD) such as filters for use in mobile communications systems.

### Description of Related Art

Wireless communications systems find applications in numerous contexts involving information transfer over long and short distances alike, and there exists a wide range of modalities suited to meet the particular needs of each. Chief amongst these systems with respect to popularity and deployment is the mobile or cellular phone.

A fundamental component of any wireless communications system is the transceiver, that is, the combined transmitter and receiver circuitry. The transceiver encodes the data to a baseband signal and modulates it with an RF carrier signal. Upon receipt, the transceiver down-converts the RF signal, demodulates the baseband signal, and decodes the data represented by the baseband signal. An antenna connected to the transmitter converts the electrical signals to electromagnetic waves, and an antenna connected to the receiver converts the electromagnetic waves back to electrical signals. Depending on the particulars of the communications modality, single or multiple antennas may be utilized. Conventional transceivers typically do not generate sufficient power or have sufficient sensitivity for reliable communications standing alone. Thus, additional conditioning of the RF signal is necessary. The circuitry between the transceiver and the antenna that provide this functionality is referred to as the front end circuit, which is understood to be comprised of a power amplifier (PA) for increased transmission power, and/or a low noise amplifier (LNA) for increased reception sensitivity. Each band or operating frequency of the communications system may have a dedicated power amplifier and low noise amplifier tuned specifically to that operating frequency. At the design and manufacturing stages of a high volume product all the wireless system blocks are tuned to operate at an optimal condition and so the system performance lags when non-ideal conditions appear.

The input and output ports of a transceiver block are always designed to operate with a 50 Ohm antenna impedance. However, in practice the antenna impedance may stray from the ideal due to size constraints and external conditions, and create a mismatch. Since an RF power amplifier in the final stage of an RF transceiver block is designed to optimally operate with a 50 Ohm antenna impedance, if the antenna does not have 50 Ohm impedance the RF power amplifier will deliver a non-optimal power to the antenna as a result of the mismatch. The power radiated from the antenna into space will be not as designed and the quality of the signal may also be degraded.

High power efficiency is an important design consideration in modern RF applications. Class D, E, F and J amplifiers are popular choices in modern RF applications in due to their highly efficient operation. Highly efficient operation is achieved by mitigating harmonic oscillations at the input and the output of the amplifier. For example, in a class F amplifier, the output of the amplifier should ideally present a short circuit path to the even ordered harmonics (e.g., 2F0, 4F0, 6F0, etc.) of the fundamental frequency F0, and the output of the amplifier should ideally present an open circuit to the odd ordered harmonics (e.g., 3F0, 5F0, 7F0 etc.) of the fundamental RF frequency F0. For this reason, harmonic filtering components such as resonators and open circuits can be used to selectively filter harmonic components of the fundamental RF frequency F0. Known techniques for improving amplifier efficiency include incorporating RF filters into the impedance matching networks of RF amplifiers. These RF filters can be incorporated into the printed circuit board (PCB) level impedance matching network and/or the package level impedance matching network. In either case, the impedance matching networks can include LC filters that are tuned to the harmonics of the fundamental frequency F0 so as to provide. One drawback of conventional harmonic tuning designs is that higher order harmonics become increasingly difficult to filter with increasing separation from the current source. For example, in the above described configurations, parasitic reactance of the package level and board level conductors substantially influences the propagation of higher frequency signals. As a result, the ability to tune high frequency harmonics, which may be in the range of 4 GHz or higher in modern RF applications, is very limited at the board level.

The present invention is focused on providing a harmonic filter which is integrated into the lead-frame of the integrated circuit package housing the front end chip(s).

The present invention provides an IC package with a harmonic filter integrated into it as well as providing further advantages as described in the following summary.

### SUMMARY OF THE INVENTION

The present invention teaches certain benefits in construction and use which give rise to the objectives described below.

A primary objective of the present invention is to provide RF transceiver circuits having advantages not taught by the prior art. The primary objective of the invention is to provide an integrated circuit package which incorporates a harmonic filter within its construction. An additional objective of the present invention is to provide for a minimized connection wire length between the antenna terminal of the front end IC and the harmonic filter by the use of a bond wire.

An secondary objective of the present invention is to provide Integrated Passive Devices (IPD's) such as a harmonic filter or Embedded Passive Components such as resistors (R), capacitors (C), inductors(L)/coils/chokes, microstriplines, impedance matching elements, baluns or any combinations of them integrated into the same package as the RF transceiver circuits.

An additional objective to the present invention is to provide a construction in which the harmonic filter is designed to present a 50 Ohm impedance to the IC FE. Finally, the proposed solution reduces size and cost associated with transceiver circuits that are fabricated in CMOS technology or applied as standalone devices. Other features and advantages of the present invention will become apparent from the following more detailed description, taken in conjunction with the accompanying drawings, which illustrate, by way of example, the principles of the invention.

### BRIEF DESCRIPTION OF THE DRAWINGS

The accompanying drawings illustrate the present invention.

FIG. 1 is a diagram illustrating the circuit blocks found in a typical RF transceiver architecture.

FIG. 2 is a diagram illustrating a package lead-frame portion of first embodiment of the invention.

FIG. 3 is a diagram illustrating a package lead-frame populated with an RF IC and an integrated harmonic filter according to a first embodiment of the invention

### DETAILED DESCRIPTION OF THE INVENTION

Various embodiments of an RF transceiver IC FE chip and package including transmitter power amplifier (PA) circuits having advantages not taught by the prior art are described herein. In the following description, numerous specific details are set forth in order to provide a thorough understanding of the present invention. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Throughout the specification and claims, the following terms take the meanings explicitly associated herein, unless the context clearly dictates otherwise. The terms “coupled” and “connected”, which are utilized herein, are defined as follows. The term “connected” is used to describe a direct connection between two circuit elements, for example, by way of a metal line formed in accordance with normal integrated circuit fabrication techniques. In contrast, the term “coupled” is used to describe either a direct connection or an indirect connection between two circuit elements. For example, two coupled elements may be directly coupled by way of a metal line, or indirectly connected by way of an intervening circuit element (e.g., a capacitor, resistor, or by way of the source/drain terminals of a transistor). The term “circuit” means either a single component or a multiplicity of components, either active or passive, that are coupled together to provide a desired function. The term “signal” means at least one current, voltage, or data signal. Although circuit elements may be fabricated on the back side, when reference is made to certain circuit elements residing within or formed in a substrate, this is generally accepted to mean the circuits reside on the front side of the substrate.

The above-described drawing figures illustrate the invention, an RF transceiver integrated circuit FE chip and package with integrated harmonic filter designed to present a 50 Ohm impedance to the integrated circuit FE chip.

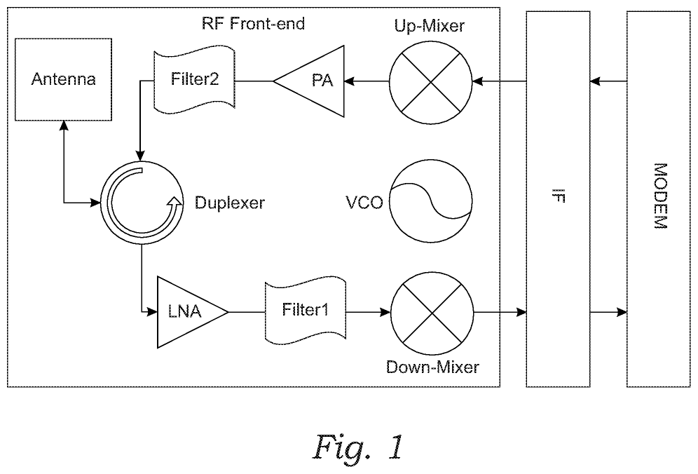

FIG. 1 is a diagram illustrating the circuit blocks found in a typical RF transceiver architecture or RF front end. With the Duplexer switch in a receive mode, an RF signal is received at Antenna and picked up by a low noise amplifier LNA and sent on to receiver components such as Filter1, Down-Mixer, IF block, and MODEM. With the Duplexer switch in transmit mode Antenna receives forward power from power amplifier PA through Filter2 and radiates power into space. If the antenna impedance is not be exactly matched to the power amplifying transmit circuits a portion of the forward power may be reflected. If the antenna impedance is not exactly matched to the low noise amplifying receive circuits the receiver sensitivity may be degraded. Also shown in FIG. 1 are a voltage controlled oscillator VCO and an Up-Mixer and a Down-Mixer which are used to up convert and down convert an input RF frequency to an intermediate frequency IF.

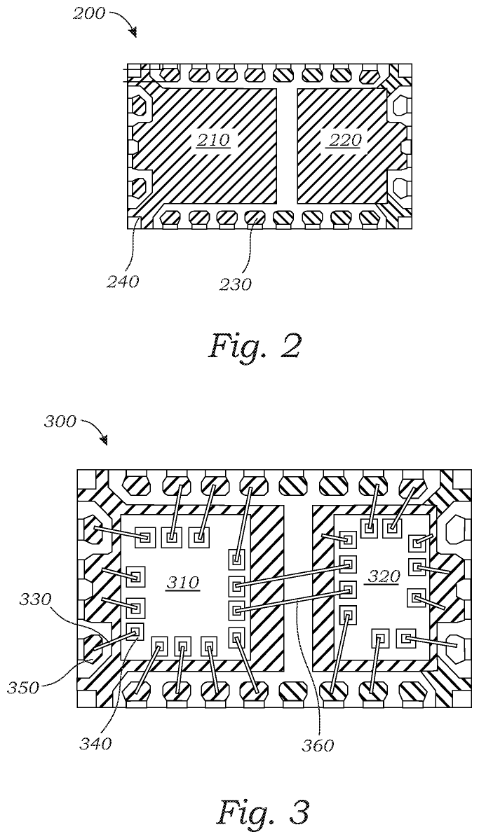

FIG. 2 is a diagram illustrating a package lead-frame 200 portion of first embodiment of the invention. Lead-frames are the metal structures inside a chip package that carry signals from the die to the outside. Classically the lead-frame consists of different parts; The central integrated circuit die pad part, where the die is to be placed, usually multiple bond pads, where the bond wires are placed to connect the chip to the outer part, and the leads, which are metal structures connecting the inside of the semiconductor package with the outside. Additionally there are mechanical connections to fix all these parts inside a frame structure, which makes the whole lead-frame easy to handle automatically. The die inside the package is typically glued or soldered to the die pad inside the lead-frame, and then bond wires connect the die to the leads via the bond pads. In the last stage of the manufacturing process, the lead-frame is molded in a plastic case, and is cut-off outside of the mold body, separating all leads by removing the holding structures at least enough to achieve an electrical insulation. A bending of the external leads can form the usual shapes seen where integrated circuit packages are soldered onto a printed circuit board.

In the illustrated lead-frame of the first embodiment of the invention there are two metal platforms or paddles 210 and 220. First metal die paddle 210 may be laterally and immediately adjacent and electrically separated from second metal die paddle 220. Die paddles 210 and 220 occupy a common plane. A number of metal bond pads 230 form an outer ring of pads surrounding the adjacent die paddles 210 and 220, wherein there are no metal bond pads between the adjacent die paddles 210 and 220 but at least two of metal bond pads 230, such as bond pads 240, connect to die paddle 210 and at least two of the metal bond pads connect to die paddle 220. In the illustrated lead-frame of the first embodiment of the invention an integrated circuit RF Front End semiconductor die or chip is mounted on one paddle and a harmonic filter or other integrated passive device is mounted on the other paddle. Lead-frame 200 may be 6 millimeters wide and 3 millimeters tall, however, in other embodiments, lead-frame may have different measurements with similar proportions.

FIG. 3 is a diagram illustrating a package lead-frame 300 populated with an RF Front End IC and an integrated harmonic filter according to a first embodiment of the invention. Lead-frame 300 is similar to lead-frame 200 shown in FIG. 2 but with RF Front End IC 310 mounted on one metal plate and harmonic filter 320 mounted on the second metal plate. This first embodiment of the invention also includes metal bond wires 330 connecting on-chip bond pads 340 with on lead-frame metal pad regions 350. One of the on-chip bond pads may be an antenna output for the RF Front End IC. One or more of lead-frame metal pads 350 may be connected to an antenna. The antenna output of the RF Front End IC may be directly connected to the harmonic filter, for example by bond wire 360. Bond wire 360 may be comprised of AuPdCu metal with 20 micron diameter. Harmonic filter 320 is designed in such a way that it presents a 50 Ohm impedance to the RF Front End IC.

Package lead-frame 300 including the two illustrated components may be encased in a mold compound such as model EME-G770HMD.

Reference throughout this specification to “one embodiment,” “an embodiment,” “one example,” or “an example” means that a particular feature, structure, or characteristic described in connection with the embodiment or example is included in at least one embodiment or example of the present invention. Thus, the appearances of the phrases such as “in one embodiment” or “in one example” in various places throughout this specification are not necessarily all referring to the same embodiment or example. Furthermore, the particular features, structures, or characteristics may be combined in any suitable manner in one or more embodiments or examples. Directional terminology such as “top”, “down”, “above”, “below” are used with reference to the orientation of the figure(s) being described. Also, the terms “have,” “include,” “contain,” and similar terms are defined to mean “comprising” unless specifically stated otherwise. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

The above description of illustrated examples of the present invention, including what is described in the Abstract, are not intended to be exhaustive or to be limited to the precise forms disclosed. While specific embodiments of, and examples for, the invention are described herein for illustrative purposes, various equivalent modifications are possible without departing from the broader spirit and scope of the present invention. Indeed, it is appreciated that the specific example structures and materials are provided for explanation purposes and that other structures and materials may also be employed in other embodiments and examples in accordance with the teachings of the present invention. These modifications can be made to examples of the invention in light of the above detailed description. The terms used in the following claims should not be construed to limit the invention to the specific embodiments disclosed in the specification and the claims. Rather, the scope is to be determined entirely by the following claims, which are to be construed in accordance with established doctrines of claim interpretation.

1. An integrated circuit lead-frame package for an RF transceiver integrated circuit front end chip with integrated harmonic filter, comprising:
a first metal die paddle and a laterally immediately adjacent and electrically separated second metal die paddle, wherein the first and second die paddles occupy a common plane, and
an RF Front End Chip affixed to the first metal die paddle with an antenna output bond pad located on the side of the first metal die paddle that is laterally immediately adjacent to the second metal die paddle, and
a Harmonic filter affixed to the second metal die paddle with a filter connection bond pad located on the side of the second metal die paddle that is laterally immediately adjacent to the first metal die paddle, and
a bond wire directly connecting the antenna output bond pad to the filter connection bond pad, wherein the bond wire provides the minimum connection wire length between the two bond pads and is designed along with the Harmonic filter to present a 50 Ohm impedance to the RF Front End Chip, and
a number of metal bond pad regions forming an outer ring of pads surrounding the adjacent first and second die paddles, wherein there are no metal bond pad regions between the adjacent die paddles but at least two of the metal bond pad regions connect to the first die paddle and at least two of the metal bond pad regions connect to the second die paddle.

2. (canceled)

3. The integrated circuit lead-frame package according to claim 1 further characterized in that the bond wire also contributes to the electrical circuit design by functioning as a low loss inductor.

4. The integrated circuit lead-frame package according to claim 1 further characterized in that the bond wire is composed of a Gold Platinum Copper alloy and is 20 microns in diameter.

5. The integrated circuit lead-frame package according to claim 1 further characterized in that outer ring of bond pad regions is 6 millimeters long and 3 millimeters wide.

6. The integrated circuit lead-frame package according to claim 1 further characterized in that the package lead-frame including the RF Front End chip and the harmonic filter are encased in a mold compound such as model EME-G770HMD.
